(19) United States
(12) Patent Application Publication
(10) Pub. No.: US 2011/0006998 A1
(43) Pub. Date: Jan. 13, 2011

(54) PATTERNING OF THIN FILM CONDUCTIVE AND PASSIVATION LAYERS

(76) Inventors: SUNGGU KANG, San Jose, CA (US); LILI HUANG, San Jose, CA (US)

Correspondence Address: APPLE c/o MOFO LA, 555 WEST FIFTH STREET SUITE 3500, SUITE 200, LOS ANGELES, CA, 90013-1024, US

(21) Appl. No.: 12/501,390

(22) Filed: Jul. 10, 2009

(51) Int. Cl. G06F 3/041; H01L 21/28

(52) U.S. Cl. 345/173; 438/669; 257/E21.158

(57) ABSTRACT

Simplified patterning of conductive layers and passivation layers of a thin film is disclosed. In some embodiments, the patterning can include depositing a conductive layer onto a thin film substrate, depositing a passivation layer onto the conductive layer, applying a removable mask including a desired pattern to the passivation layer, patterning the passivation layer to have the desired pattern, using the patterned passivation layer as a mask for the conductive layer, and patterning the conductive layer to have the desired pattern. In other embodiments, the patterning can include depositing a conductive layer onto a thin film substrate, depositing a passivation layer onto the conductive layer, depositing a protective layer onto the passivation layer, applying a removable mask including a desired pattern to the protective layer, patterning the protective layer to have the desired pattern, using the patterned protective layer as a mask for the passivation and conductive layers, and patterning the passivation and conductive layers to have the desired pattern. An exemplary device utilizing the thin film so patterned can include a touch sensor panel.

### FIELD

This relates generally to thin film patterning, and more particularly, to the simplified patterning of conductive and passivation layers of a thin film.

### BACKGROUND

The conventional process for patterning conductive layers and passivation layers on a thin film involves two separate patterning procedures. Typically, the conductive layer patterning and then the passivation layer patterning are done. The conductive layer patterning is done to form conductive traces on the thin film in a desired pattern so as to conduct electrical signals according to the needs of the thin film device. Because the conductive traces can be very thin, the passivation layer patterning is done to form a protective pattern for material, e.g., metal, underlying the traces and subject to corrosion from downstream processes and the environment.

Patterning the conductive layer involves, inter alia, depositing a conductive layer on a dielectric (or insulator) layer, which is disposed on a metal layer, coating the conductive layer with a photosensitive (or photo resist) layer, applying a photo mask having the conductive layer desired pattern, exposing the photo mask to light, developing the photosensitive layer to correspond to the mask pattern, thereby exposing certain areas of the conductive layer for forming into the desired pattern, etching the conductive layer into the desired pattern, and chemically stripping the remaining photosensitive layer from the conductive layer. Patterning the passivation layer involves, inter alia, coating the patterned conductive layer with a passivation layer, applying a second photo mask having the passivation layer desired pattern, exposing the photo mask to light, and developing the passivation layer to correspond to the mask pattern, thereby protecting the underlying metal layer from chemical and mechanic attack during further thin film fabrication. The passivation layer can selectively coat portions of the conductive layer that need to be protected, while not coating other portions of the conductive layer that need to be exposed.

This conventional process can become particularly complex when patterning conductive layers and passivation layers of a touch sensor panel, which can have multiple conductive traces forming drive and sense lines as well as other conductive components. For example, performing separate conductive layer patterning and passivation layer patterning can increase the amount of time needed to form the patterns, the amount of material needed, e.g., two photo masks, the amount of equipment needed, the power consumption, the associated costs, and so on.

### SUMMARY

This relates to simplified patterning of conductive and passivation layers of a thin film used in devices such as touch sensor panels. The patterning can include depositing a conductive layer onto a thin film substrate, depositing a passivation layer onto the conductive layer, applying a removable mask including a desired pattern to the passivation layer, patterning the passivation layer to have the desired pattern, using the patterned passivation layer as a mask for the conductive layer, and patterning the conductive layer to have the desired pattern. In addition or alternatively, the patterning can include depositing a conductive layer onto a thin film substrate, depositing a passivation layer onto the conductive layer, depositing a protective layer onto the passivation layer, applying a removable mask including a desired pattern to the protective layer, patterning the protective layer to have the desired pattern, using the patterned protective layer as a mask for the passivation and conductive layers, and patterning the passivation and conductive layers to have the desired pattern. This simplified patterning can advantageously realize cost, power, and time savings over the conventional process.

### BRIEF DESCRIPTION OF THE DRAWINGS

FIG. 1 illustrates an exemplary touch sensor panel having conductive bridges and bonding areas formed by simplified patterning of conductive and passivation layers according to various embodiments.

FIGS. 2a-2g illustrate an exemplary conductive bridge formed by simplified patterning of conductive and passivation layers according to various embodiments.

FIGS. 3a-3f illustrate an exemplary bonding area formed by simplified patterning of conductive and passivation layers according to various embodiments.

FIGS. 4a-4b illustrate an exemplary patterning of a photosensitive material using an exemplary photo mask according to various embodiments.

FIG. 5 illustrates another exemplary photo mask that can be used for patterning of a photosensitive material according to various embodiments.

FIG. 6 illustrates an exemplary method for simplified patterning of conductive and passivation layers of a touch sensor panel according to various embodiments.

FIGS. 7a-7i illustrate another exemplary conductive bridge formed by simplified patterning of conductive and passivation layers according to various embodiments.

FIGS. 8a-8h illustrate another exemplary bonding area formed by simplified patterning of conductive and passivation layers according to various embodiments.

FIG. 9 illustrates another exemplary method for simplified patterning of conductive and passivation layers of a touch sensor panel according to various embodiments.

FIG. 10 illustrates an exemplary mobile telephone having a touch sensor panel that includes conductive bridges and bonding areas formed by simplified patterning of conductive and passivation layers according to various embodiments.

FIG. 11 illustrates an exemplary digital media player having a touch sensor panel that includes conductive bridges and bonding areas formed by simplified patterning of conductive and passivation layers according to various embodiments.

FIG. 12 illustrates an exemplary computer having a touch sensor panel that includes conductive bridges and bonding areas formed by simplified patterning of conductive and passivation layers according to various embodiments.

FIG. 13 illustrates an exemplary computing system including a touch sensor panel utilizing conductive bridges and bonding areas thereon formed by simplified patterning of conductive and passivation layers according to various embodiments.

FIG. 14 illustrates another exemplary method for simplified patterning of conductive and passivation layers of a thin film that can be used in an electronic device according to various embodiments.

FIG. 15 illustrates an exemplary method for patterning of a metal layer (or a dielectric layer) of a touch sensor panel according to various embodiments.

### DETAILED DESCRIPTION

In the following description of various embodiments, reference is made to the accompanying drawings which form a part hereof, and in which it is shown by way of illustration specific embodiments which may be practiced. It is to be understood that other embodiments may be utilized and structural changes may be made without departing from the scope of the various embodiments.

This relates to patterning of thin film conductive and passivation layers, which can be simpler than patterning in a conventional process. This patterning can be used for touch sensor panels to form conductive bridges between drive and sense conductive traces and to form bonding areas to connect the panel to other circuitry. In some embodiments, the patterning can include depositing a conductive layer onto a thin film substrate, depositing a passivation layer onto the conductive layer, applying a removable mask including a desired pattern to the passivation layer, patterning the passivation layer to have the desired pattern, using the patterned passivation layer as a mask for the conductive layer, and patterning the conductive layer to have the desired pattern. In other embodiments, the patterning can include depositing a conductive layer onto a thin film substrate, depositing a passivation layer onto the conductive layer, depositing a protective layer onto the passivation layer, applying a removable mask including a desired pattern to the protective layer, patterning the protective layer to have the desired pattern, using the patterned protective layer as a mask for the passivation and conductive layers, and patterning the passivation and conductive layers to have the desired pattern.

This simplified patterning can advantageously remove the need for two removable masks—one for patterning the conductive layer and another for patterning the passivation layer—as in the conventional process. Rather the patterned passivation layer or protective layer can function as a mask. This patterning can also reduce the actions required by the conventional process, including omitting chemical stripping of the protective layer in some instances. Accordingly, this patterning can save cost, power, and time over the conventional process.

Although various embodiments are described and illustrated herein in terms of touch sensor panels, it should be understood that the embodiments are not so limited to such panels, but are generally applicable to panels utilizing other touch and proximity sensing technologies, and any device for which conductive and passivation layer patterning can be applied.

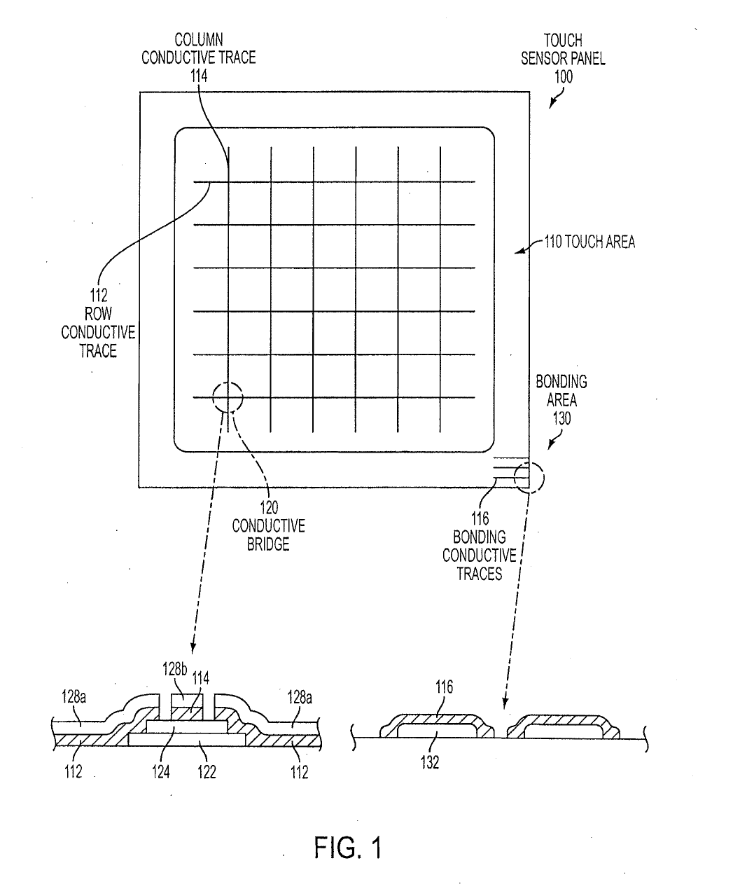

FIG. 1 illustrates an exemplary touch sensor panel having conductive bridges and bonding areas formed by simplified patterning of conductive and passivation layers according to various embodiments. In the example of FIG. 1, touch sensor panel 100 can include touch area 110. The touch area 110 can include multiple row conductive traces 112 and column conductive traces 114, forming touch sensors that can be used to sense a touch at the touch area. The row traces 112 and the column traces 114 can be formed to cross each other on a thin film. To minimize the traces 112, 114 having physical contact, which would adversely affect operation of the panel 100, conductive bridge 120 can be formed at each crossing. A cross section of an exemplary conductive bridge is illustrated in FIG. 1. The conductive bridge 120 can include metal layer 122 formed on the thin film surface, dielectric layer 124 formed on the metal layer, row conductive trace 112 formed on the thin film surface and contacting the metal and dielectric layers, column conductive trace 114 formed on the dielectric layer, and passivation layer 128a and 128b formed on the row and column traces. The conductive bridge 120 can be formed using simplified patterning of the conductive traces and the passivation layer according to various embodiments. Example formations will be described later.

In operation, the conductive bridge 120 can conduct electrical signals along crossing row trace 112 and column trace 114 without the signals interacting to adversely affect the touch panel operation. The row conductive trace 112 can conduct electrical signals along the left row trace, through the metal layer 122, and along the right row trace of the conductive bridge 120 to drive the touch sensor panel 100. The column conductive trace 114 can conduct electrical signals along the top of the conductive bridge 120 to transmit signals indicative of a touch at the panel 100. Alternatively, the column trace 114 can conduct drive signals and the row trace 112 can conduct touch signals.

The touch sensor panel 100 can also include bonding area 130. The bonding area 130 can include multiple bonding conductive traces 116, forming input/output connections for other circuitry, e.g., flex circuits, controllers, processors, and the like, to bond to the touch sensor panel 100. The conductive traces 116 can be formed near a boundary of a thin film in parallel lines, for example. A cross section of exemplary bonding traces is illustrated in FIG. 1. So that the bonding traces 116 can electrically connect with other circuitry, the bonding traces can include metal layer 132 formed on the thin film surface and conductive traces 116 surrounding the metal layer. Example formations will be described later.

In operation, the bonding area 130 can conduct electrical signals back and forth along the bonding traces between the touch sensor panel 100 and other circuitry. Example signals can include the touch signals from the touch area 110, commands from a controller to search for a touch, and so on.

It is to be understood that the touch sensor panel of FIG. 1 is not limited to that shown, but can include other components, configurations, and operations according to various embodiments.

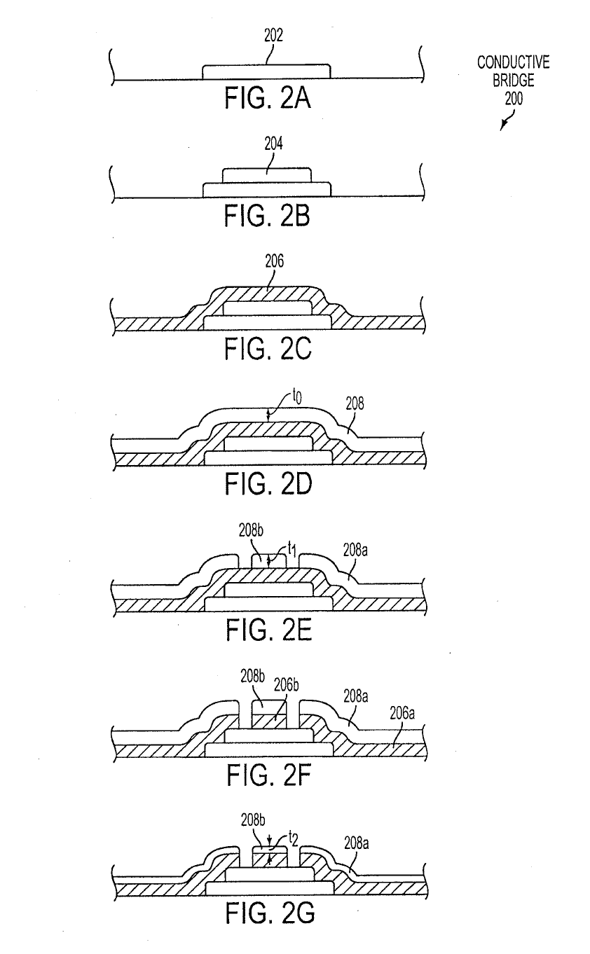

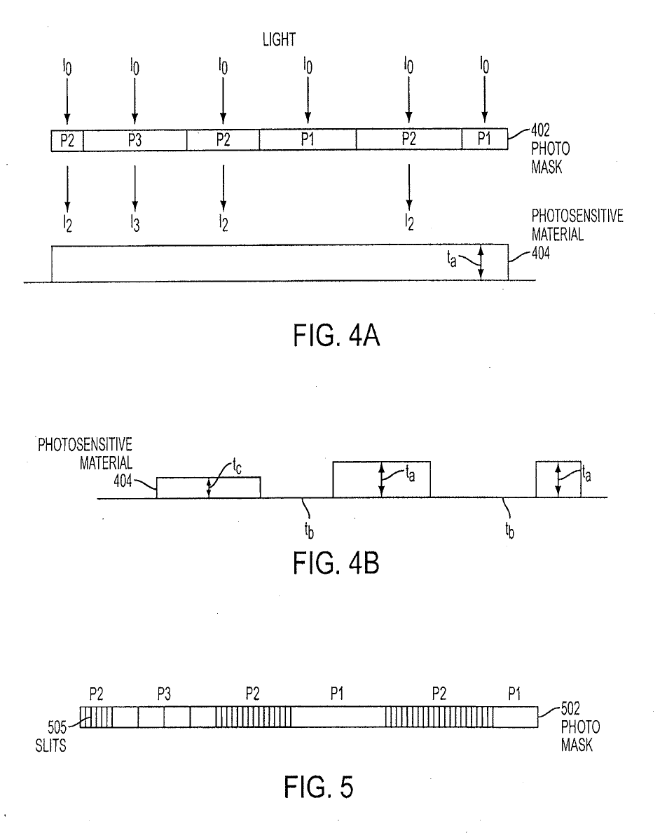

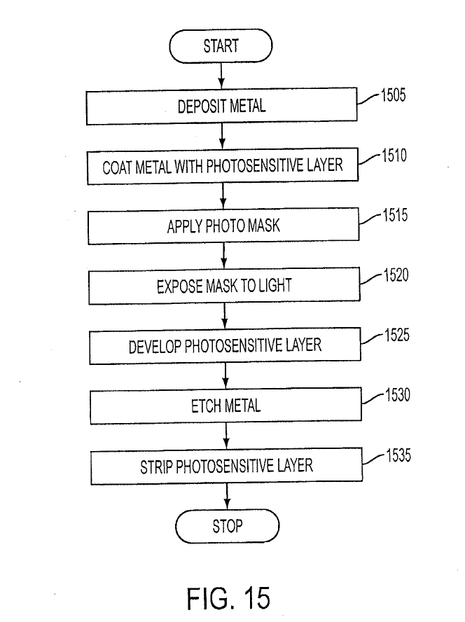

FIGS. 2a-2g illustrate an exemplary conductive bridge of a touch sensor panel formed by simplified patterning of conductive and passivation layers according to various embodiments. In the example of FIG. 2a, metal layer 202 can be patterned onto a thin film substrate, e.g., according to the method of FIG. 15, as described later. In the example of FIG. 2b, dielectric layer 204 can be patterned onto the metal layer 202, e.g., according to a similar method to that of FIG. 15, as described later. In the example of FIG. 2c, conductive layer 206 can be deposited over the metal layer 202 and the dielectric layer 204. The conductive layer 206 can be an indium-tin-oxide (ITO) layer, for example. In the example of FIG. 2d, passivation layer 208 can be deposited on the conductive layer 206. The passivation layer 208 can have a thickness tₒ and can be a photosensitive material. The passivation layer 208 can be either organic or inorganic. In the example of FIG. 2e, the passivation layer 208 can be developed using a removable photo mask having the desired conductive layer pattern, as illustrated in FIGS. 4a-4b and 5, to form that pattern.

FIGS. 4a-4b illustrate an exemplary patterning of a photosensitive material using an exemplary photo mask according to various embodiments. In the example of FIG. 4a, photo mask 402 can include portions having various transparencies (also known as a half-tone mask). In this example, portion P1 can be black or non-transparent, portion P2 can be clear or transparent, and portion P3 can be gray or semi-transparent. The amount of transparency of each portion can determine the light intensity transmitted through that portion of the photo mask 402. Here, the photo mask 402 can be exposed to light having an intensity Iₒ. Because portion P1 is non-transparent, this portion can not transmit any of the light. Because portion P2 is transparent, this portion can transmit light at an intensity I₂ close to the original intensity Iₒ, where I₂<Iₒ. Because portion P3 is semi-transparent, this portion can transmit light at a lower intensity I₃ than either I₂ or Iₒ, where 0<I₃<I₂<Iₒ. Photosensitive material 404 can have an initial thickness tₐ. When the light at various intensities hit the photosensitive material 404, the light can trigger a chemical reaction of the material proportionate to the light's intensity, thereby eliminating the reacting material. This can be known as “developing” the photosensitive material.

FIG. 4b illustrates an example of the photosensitive material 404 after it has been developed after being exposed to light through the photo mask 402. Here, the material 404 proximate to portion P1 of the photo mask 402 retained its thickness tₐ because it was not exposed to any light and therefore did not react. The material 404 proximate to portion P2 of the photo mask 402 was eliminated (indicated by t_{b}) because it was exposed to enough light to react all of the material. The material 404 proximate to portion P3 of the photo mask 402 reduced its thickness to t_{c} because it was exposed to sufficient light to partially react.

FIG. 5 illustrates another exemplary photo mask that can be used for patterning of a photosensitive material according to various embodiments. In the example of FIG. 5, photo mask 502 can include portions having various slit densities (also known as a slit mask), rather than various transparencies as in FIG. 4a. In this example, portion P1 can have no slits, allowing no light to penetrate the portion. Portion P2 can have a high slit density, allowing substantial light to penetrate the portion. Portion P3 can have a sparser slit density, allowing moderate light to penetrate the portion. The photo mask 502 can affect a photosensitive material similarly as described above.

Referring again to FIG. 2e, a photo mask similar to those of FIGS. 4a and 5 can be applied to the conductive bridge 200 to form a desired pattern. For example, a photo mask can be applied to the passivation layer 208, where the photo mask can have transparent (or high slit density) portions where the layer is eliminated and non-transparent (or no slit) portions everywhere else.

In the example of FIG. 2f, the conductive layer 206 can be etched to form the desired pattern, where left and right portions of the layer 206a can form row traces and the middle portion of the layer 206b can form column traces. Here, rather than using a second mask as in the conventional process, the patterned passivation layer 208a, 208b can function as the etching mask for the conductive layer 206, resulting in a simplified patterning. In the example of FIG. 2g, excess passivation layer 208 can be easily removed, e.g., by ashing using oxygen plasma, such that the layer can have a lower thickness t₂. As such, this removal can replace the chemical stripping of the conventional process. The passivation layer 208 can function to protect the metal layer 202 from corrosion in downstream processes and in the environment. The resulting conductive bridge 200 can transmit electrical signals of a touch sensor panel, as described previously. In this example, the passivation layer 208 can have dual functions—as a patterning mask for the conductive layer and as a passivation layer for the metal layer.

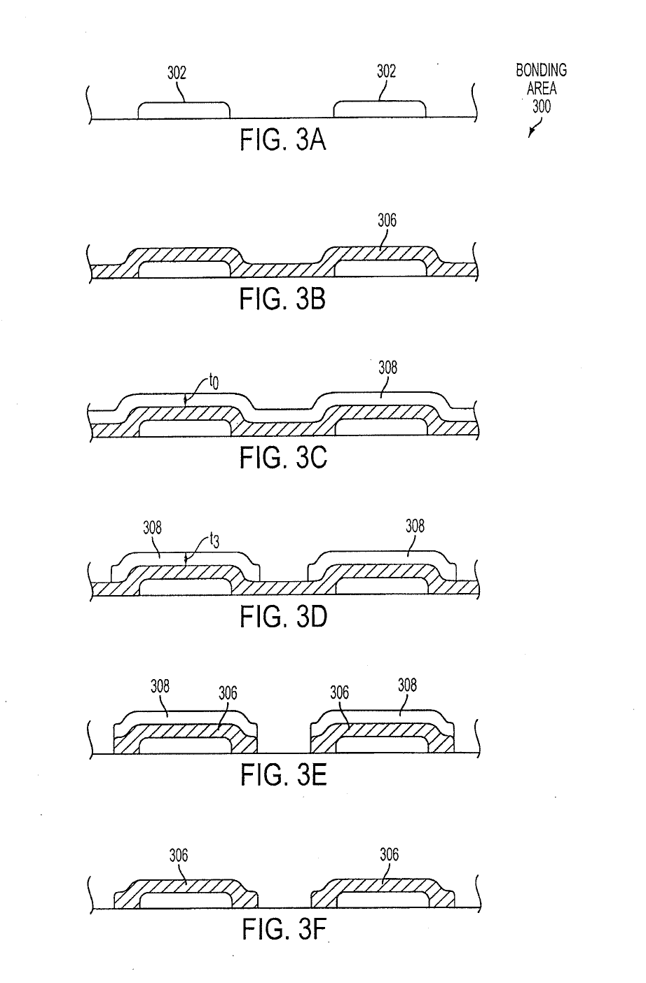

FIGS. 3a-3f illustrate an exemplary bonding area of a touch sensor panel formed by simplified patterning of conductive and passivation layers according to various embodiments. In the example of FIG. 3a, metal layers 302 can be patterned onto a thin film substrate, e.g., as described in FIG. 15. In the example of FIG. 3b, conductive layer 306 can be deposited over the metal layers 302. The conductive layer 306 can be an ITO layer. In the example of FIG. 3c, passivation layer 308 can be deposited on the conductive layer 306. The passivation layer 308 can have a thickness tₒ and can be photosensitive material. In the example of 3d, the passivation layer 308 can be developed using a removable photo mask having the desired conductive layer pattern to form that pattern. For example, a photo mask similar to those of FIGS. 4a and 5 can be applied to the passivation layer 308, where the photo mask can have transparent (or high slit density) portions where the layer is eliminated and semi-transparent (or lower slit density) where the layer thickness is reduced to t₃. In the example of FIG. 3e, the conductive layer 306 can be etched to form the desired pattern, where the layers can form bonding conductive traces. Here, rather than using a second mask as in the conventional process, the patterned passivation layer 308 can function as the etching mask for the conductive layer 306, resulting in a simplified patterning. In the example of FIG. 2f, the remaining passivation layer 308 can be easily removed, e.g., by ashing, such that the conductive layer 306 can be available for bonding with other circuitry. This removal can replace the chemical stripping of the conventional process.

The simplified patterning of FIGS. 2a-2g and 3a-3f can be performed concurrently. The metal layers 202, 302 can be patterned onto the thin film substrate as in FIGS. 2a and 3a. The dielectric layer 204 can be patterned onto the metal layer 202 as in FIG. 2b. The conductive layers 206, 306 can be deposited as in FIGS. 2c and 3b. The passivation layers 208, 308 can be deposited with thickness tₒ as in FIGS. 2d and 3c. A photo mask can be applied over all or portions of the thin film substrate. The section of the mask covering the conductive bridge 200 can have a transparent (or high slit density) portion over the passivation layer 208 where the layer is eliminated and an almost non-transparent (or low slit density) portion over the passivation layer everywhere else to reduce the layer thickness to t₁, which is slightly less than tₒ, as in FIG. 2e. The section of the mask covering the bonding area 300 can have a transparent (or high slit density) portion over the passivation layer 308 where the layer is eliminated and a semi-transparent (or moderate slit density) portion over the passivation layer everywhere else to reduce the layer thickness to t₃, which is less than t₁ and tₒ, as in FIG. 3d. The conductive layers 206, 306 can be etched to form conductive patterns as in FIGS. 2f and 3e. The passivation layer thicknesses t₃ and t₁ can be different for the bonding area 300 and the conductive bridge 200, where t₁>t₃, so that, at the same time, all of the passivation layer 308 can be removed from the bonding area, as in FIG. 3f, while only excess portions of the passivation layer 208 can be removed from the conductive bridge to thickness t₂, where t₂<t₁, as in FIG. 2g.

It is to be understood that patterning is not limited to that illustrated here, but can include other and/or additional components according to various embodiments.

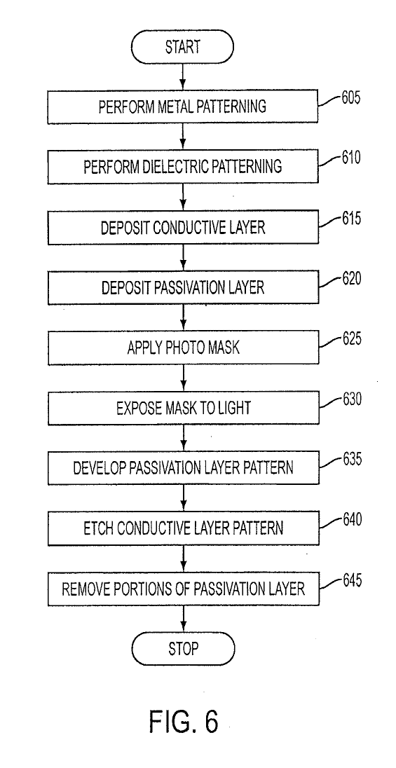

FIG. 6 illustrates an exemplary method for simplified patterning of conductive and passivation layers of a touch sensor panel according to various embodiments. This method can be used to form the conductive bridge of FIGS. 2a-2g and the bonding area of FIGS. 3a-3f. In the example of FIG. 6, metal patterning can be performed to pattern a metal layer onto a base substrate (605). Dielectric patterning can be performed to pattern a dielectric layer onto selected portions of the metal layer (610). A conductive layer can be deposited over the dielectric layer and the metal layer (615). A photosensitive passivation layer can be deposited over the conductive layer (620). A removable photo mask can be applied over the passivation layer, where the photo mask can include the desired pattern for the conductive layer (625). The mask can be exposed to light (630). The passivation layer can be developed into the desired pattern based on the mask, thereby exposing particular portions of the conductive layer for patterning (635). The passivation layer can act as an etching mask for the conductive layer, where the exposed portions of the conductive layer can be etched to form the desired pattern (640). Selected portions of the passivation layer can be removed (645). In the case of the bonding area or other conductive traces that should be exposed, all of the passivation layer can be removed from the conductive layer. In the case of the conductive bridge or other conductive traces that should be protected, some or none of the passivation layer can be removed from the conductive layer.

It is to be understood that the method is not limited to that described in FIG. 6, but can include other or additional actions for simplified patterning of conductive and passivation layers.

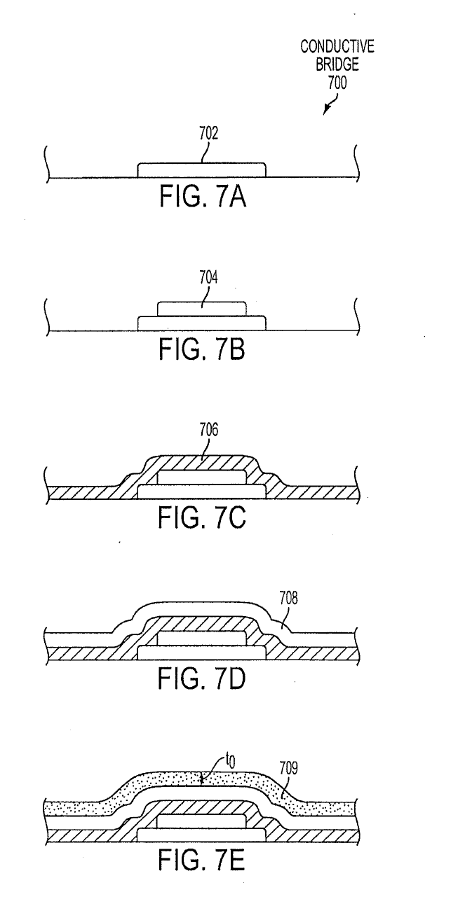

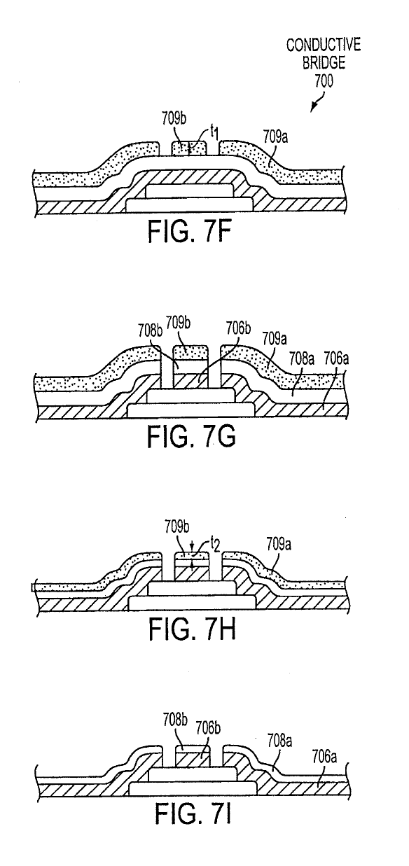

FIGS. 7a-7i illustrate another exemplary conductive bridge of a touch sensor panel formed by simplified patterning of conductive and passivation layers according to various embodiments. In the example of FIG. 7a, metal layer 702 can be patterned onto a thin film substrate, e.g., as described in FIG. 15. In the example of FIG. 7b, dielectric layer 704 can be patterned onto the metal layer 702, e.g., similar to the method described in FIG. 15. In the example of FIG. 7c, conductive layer 706 can be deposited over the metal layer 702 and the dielectric layer 704. The conductive layer 706 can be an ITO layer, for example. In the example of FIG. 7d, passivation layer 708 can be deposited on the conductive layer 706. The passivation layer 708 can be a non-photosensitive material. In the example of FIG. 7e, photosensitive (or photo resist) layer 709 can be deposited on the passivation layer 708. The photosensitive layer 709 can have a thickness tₒ. In the example of FIG. 7f, the photosensitive layer 709 can be developed using a removable photo mask having the desired conductive layer pattern, similar to those of FIGS. 4a and 5, to form that pattern. For example, the photo mask can have transparent (or high slit density) portions where the photosensitive layer 709 is eliminated and non-transparent (or no slit) portions everywhere else.

In the example of FIG. 7g, the conductive layer 706 and the passivation layer 708 can be etched to form the desired pattern, where left and right portions of the conductive layer 706a can form row traces and the middle portion of the conductive layer 706b can form column traces. Similarly, left and right portions of the passivation layer 708a can cover the left and right portions of the conductive layer 706a and the middle portion of the passivation layer 708b can cover the middle portion of the conductive layer 706b. Rather than using a second mask as in the conventional process, the patterned photosensitive layer 709a, 709b can function as the etching mask for the conductive layer 706 and the passivation layer 708, resulting in a simplified patterning. In the example of FIG. 7h, excess photosensitive layer 709 can be easily removed, e.g., by ashing, such that the layer can have a lower thickness t₂. The remaining photosensitive layer 709 can function to temporarily protect the passivation layer 708 during any further patterning of touch sensor panel components. In the example of FIG. 7i, the remaining photosensitive layer 709 can be chemically stripped from the passivation layer 708. The passivation layer 708 can function to protect the metal layer 702 from corrosion during downstream processes or in the environment. The resulting conductive bridge 700 can transmit electrical signals of a touch sensor panel, as described previously.

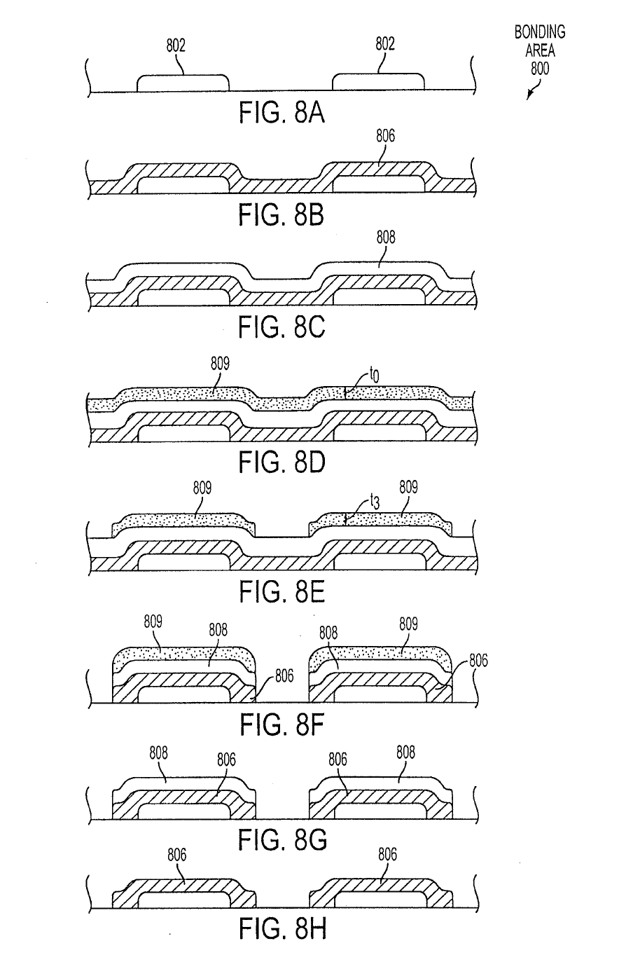

FIGS. 8a-8h illustrate another exemplary bonding area of a touch sensor panel formed by simplified patterning of conductive and passivation layers according to various embodiments. In the example of FIG. 8a, metal layers 802 can be patterned onto a thin film substrate, e.g., as described in FIG. 15. In the example of FIG. 8b, conductive layer 806 can be deposited over the metal layers 802. The conductive layer 806 can be an ITO layer. In the example of FIG. 8c, passivation layer 808 can be deposited on the conductive layer 806. The passivation layer 808 can be a non-photosensitive material. In the example of FIG. 8d, photosensitive (or photo resist) layer 809 can be deposited on the passivation layer 808. The photosensitive layer 809 can have a thickness tₒ. In the example of 8e, the photosensitive layer 809 can be developed using a photo mask having the desired conductive layer pattern to form that pattern. For example, a photo mask similar to those of FIGS. 4a and 5 can be applied to the photosensitive layer 809, where the photo mask can have transparent (or high slit density) portions where the photosensitive layer is eliminated and semi-transparent (or lower slit density) where the layer thickness is reduced to t₃. In the example of FIG. 8f, the passivation layer 808 and the conductive layer 806 can be etched to form the desired pattern, where the layers can form bonding conductive traces. Rather than using a second mask as in the conventional process, the patterned photosensitive layer 809 can function as the etching mask for the passivation layer 808 and the conducting layer 806, resulting in a simplified patterning. In the example of FIG. 8g, the remaining photosensitive layer 809 can be easily removed, e.g., by ashing. In the example of FIG. 8h, the passivation layer 808 can be further etched to remove the layer, such that the conductive layer 806 can be available for bonding with other circuitry.

The simplified patterning of FIGS. 7a-7i and 8a-8g can be performed concurrently. The metal layers 702, 802 can be patterned onto the thin film substrate as in FIGS. 7a and 8a. The dielectric layer 804 can be patterned onto the metal layer 802 of the conductive bridge 700 as in FIG. 7b. The conductive layers 706, 806 can be deposited as in FIGS. 7c and 8b. The passivation layers 708, 808 can be deposited as in FIGS. 7d and 8c. The photosensitive layers 709, 809 can be deposited with thickness tₒ as in FIGS. 7e and 8d. A removable photo mask can be applied over all or portions of the thin film substrate. The section of the mask covering the conductive bridge 700 can have a transparent (or high slit density) portion over the photosensitive layer 709 where the layer is eliminated and an almost non-transparent (or low slit density) portion over the photosensitive layer everywhere else to reduce the layer thickness to t₁, which is slightly less than tₒ, as in FIG. 7f. The section of the mask covering the bonding area 800 can have a transparent (or high slit density) portion over the photosensitive layer 809 where the layer is eliminated and a semi-transparent (or moderate slit density) portion over the photosensitive layer everywhere else to reduce the layer thickness to t₃, which is less than t₁ and tₒ, as in FIG. 8e. The conductive layers 706, 806 and the passivation layers 708, 808 can be etched to form desired patterns as in FIGS. 7g and 8f. The photosensitive layer thicknesses t₃ and t₁ can be different for the bonding area 800 and the conductive bridge 700, where t₁>t₃, such that, at the same time, all of the photosensitive layer 809 can be removed from the bonding area, as in FIG. 3g, while only excess portions of the photosensitive layer 709 can be removed from the conductive bridge to thickness t₂, where t₂<t₁, as in FIG. 7h, in order to protect the passivation layer 708 during further patterning.

The passivation layer 808 on the bonding area 800 can be further etched to remove the layer as in FIG. 8h, while the remaining photosensitive layer 709 on the conductive bridge 700 can protect the passivation layer 708 from the etching as in FIG. 7h. The remaining photosensitive layer 709 on the conductive bridge 700 can be stripped as in FIG. 7i.

It is to be understood that patterning is not limited to that illustrated here, but can include other and/or additional components according to various embodiments.

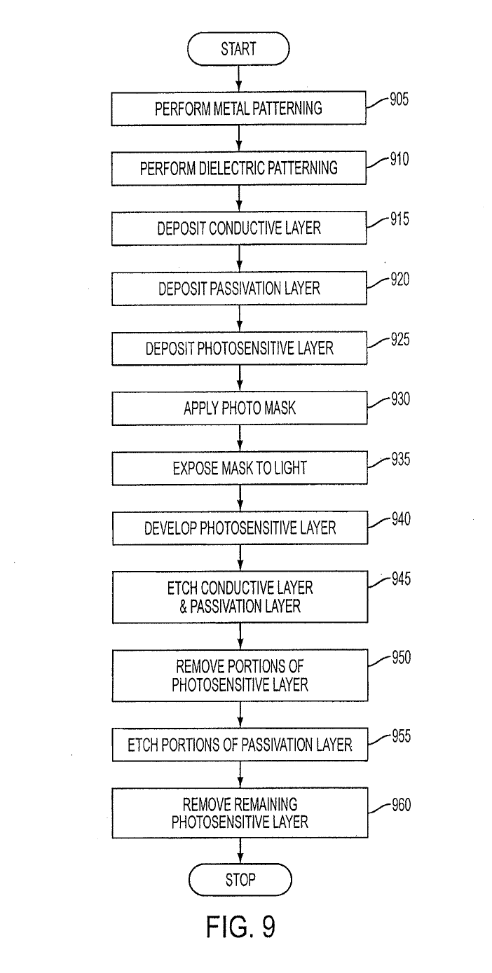

FIG. 9 illustrates another exemplary method for simplified patterning of conductive and passivation layers of a touch sensor panel according to various embodiments. This method can be used to form the conductive bridge of FIGS. 7a-7i and the bonding area of FIGS. 8a-8g. In the example of FIG. 9, metal patterning can be performed to pattern a metal layer onto a base substrate (905). Dielectric patterning can be performed to pattern a dielectric layer onto selected portions of the metal layer (910). A conductive layer can be deposited over the dielectric layer and the metal layer (915). A non-photosensitive passivation layer can be deposited over the conductive layer (920). A photosensitive (or photo resist) layer can be deposited over the passivation layer (925). A removable photo mask can be applied over the photosensitive layer, where the photo mask can include the desired pattern for the conductive layer (930). The mask can be exposed to light (935). The photosensitive layer can be developed into the desired pattern based on the mask, thereby exposing particular portions of the passivation layer and the conductive layer for patterning (940). The patterned photosensitive layer can function as an etching mask for the passivation layer, where the exposed portions of the passivation layer can be etched to form the desired pattern, and similarly the patterned passivation layer can function as an etching mask for the conductive layer, where the exposed portions of the conductive layer can be etched to form the desired pattern (945). Selected portions of the photosensitive layer can be removed (950). In the case of the bonding area or other conductive traces that should be open, all of the photosensitive layer can be removed from the passivation layer. In the case of the conductive bridge or other conductive traces that should be protected, some or none of the photosensitive layer can be removed from the passivation layer. The exposed portions of the passivation layer can be further etched (955). In the case of the bonding area or other conductive traces that should be open, all of the passivation layer can be etched from the conductive layer, thereby exposing the conductive layer for bonding with other circuitry. The remaining photosensitive layer can be removed from the passivation layer (960). In the case of the conductive bridge or other conductive traces that should be protected, the passivation layer can protect the underlying components.

It is to be understood that the method is not limited to that described in FIG. 9, but can include other or additional actions for simplified patterning of conductive and passivation layers.

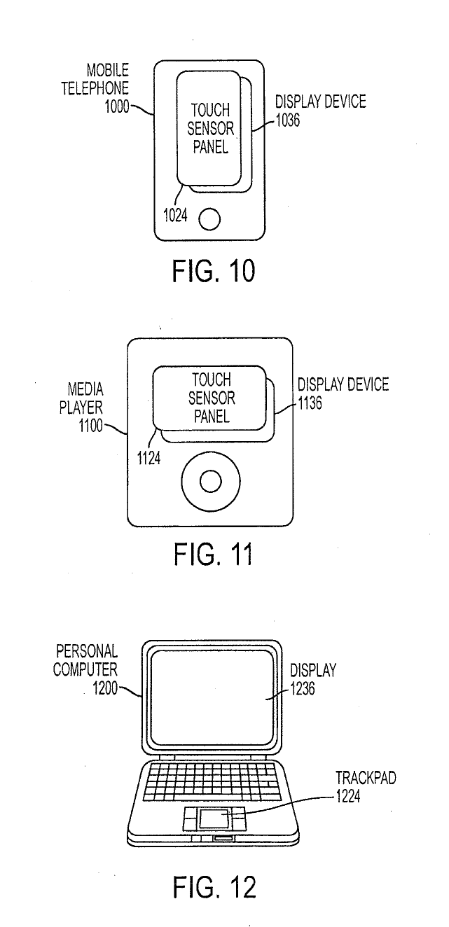

FIG. 10 illustrates an exemplary mobile telephone 1000 that can include touch sensor panel 1024, display device 1036, and other computing system blocks, where the touch sensor panel can have conductive bridges and bonding areas formed by simplified patterning of conductive and passivation lines.

FIG. 11 illustrates an exemplary digital media player 1100 that can include touch sensor panel 1124, display device 1136, and other computing system blocks, where the touch sensor panel can have conductive bridges and bonding areas formed by simplified patterning of conductive and passivation lines.

FIG. 12 illustrates an exemplary personal computer 1200 that can include touch sensor panel (trackpad) 1224 and display 1236, and other computing system blocks, where the touch sensor panel can have conductive bridges and bonding areas formed by simplified patterning of conductive and passivation lines.

The mobile telephone, media player, and personal computer of FIGS. 10 through 12 can have conductive and passivation layer patterns formed in a simplified manner according to various embodiments, thereby realizing cost, time, and power savings.

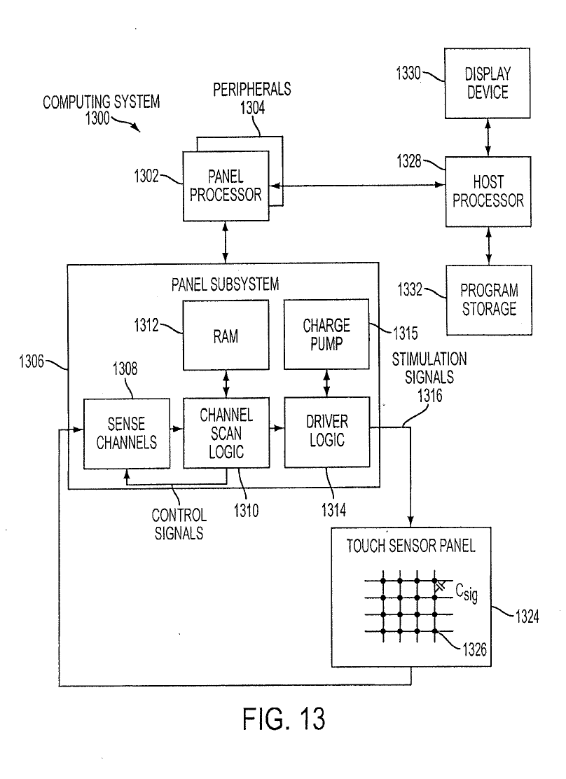

FIG. 13 illustrates exemplary computing system 1300 that can include one or more of the embodiments of the invention described above. Computing system 1300 can include one or more panel processors 1302 and peripherals 1304, and panel subsystem 1306. Peripherals 1304 can include, but are not limited to, random access memory (RAM) or other types of memory or storage, watchdog timers and the like. Panel subsystem 1306 can include, but is not limited to, one or more sense channels 1308, channel scan logic 1310 and driver logic 1314. Channel scan logic 1310 can access RAM 1312, autonomously read data from the sense channels and provide control for the sense channels. In addition, channel scan logic 1310 can control driver logic 1314 to generate stimulation signals 1316 at various frequencies and phases that can be selectively applied to drive lines of touch sensor panel 1324. In some embodiments, panel subsystem 1306, panel processor 1302 and peripherals 1304 can be integrated into a single application specific integrated circuit (ASIC).

Touch sensor panel 1324 can include a capacitive sensing medium having multiple drive lines and sense lines, although other sensing media can also be used. The drive and sense lines and conductive bridges at the crossings of the drive and sense lines can be formed using simplified patterning according to various embodiments. Each crossing of the drive and sense lines can represent a capacitive sensing node and can be viewed as picture element (pixel) 1326, which can be particularly useful when touch sensor panel 1324 is viewed as capturing an “image” of touch. (In other words, after panel subsystem 1306 has determined whether a touch event has been detected at each touch sensor in the touch sensor panel, the pattern of touch sensors in the multi-touch panel at which a touch event occurred can be viewed as an “image” of touch (e.g. a pattern of fingers touching the panel).) Each sense line of touch sensor panel 1324 can drive sense channel 1308 (also referred to herein as an event detection and demodulation circuit) in panel subsystem 1306.

Computing system 1300 can also include host processor 1328 for receiving outputs from panel processor 1302 and performing actions based on the outputs that can include, but are not limited to, moving an object such as a cursor or pointer, scrolling or panning, adjusting control settings, opening a file or document, viewing a menu, making a selection, executing instructions, operating a peripheral device coupled to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. Host processor 1328 can also perform additional functions that may not be related to panel processing, and can be coupled to program storage 1332 and display device 1330 such as an LCD panel for providing a UI to a user of the device. Display device 1330 together with touch sensor panel 1324, when located partially or entirely under the touch sensor panel, can form touch screen 1318.

Note that one or more of the functions described above can be performed by firmware stored in memory (e.g. one of the peripherals 1304 in FIG. 13) and executed by panel processor 1302, or stored in program storage 1332 and executed by host processor 1328. The firmware can also be stored and/or transported within any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any medium that can contain or store the program for use by or in connection with the instruction execution system, apparatus, or device. The computer readable medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport readable medium can include, but is not limited to, an electronic, magnetic, optical, electromagnetic or infrared wired or wireless propagation medium.

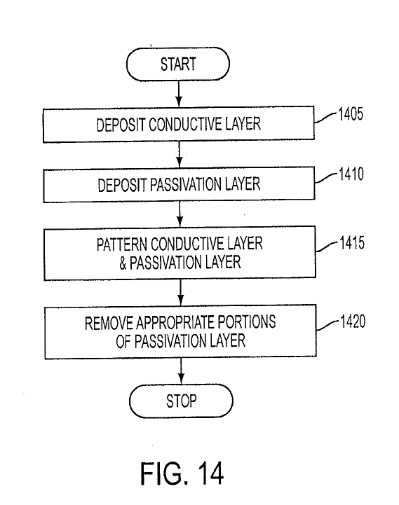

FIG. 14 illustrates an exemplary method for simplified patterning of conductive and passivation layers of a thin film that can be used in an electronic device according to various embodiments. In the example of FIG. 14, a conductive layer can be deposited on a substrate (1405). A passivation layer can be deposited on the conductive layer (1410). The conductive layer and the passivation layer can be patterned to form a same or similar pattern (1415). The layers can be patterned together or in succession according to various embodiments. Appropriate portions of the passivation layer can be removed from the conductive layer (1420).

FIG. 15 illustrates an exemplary method for patterning of a metal layer of a touch sensor panel according to various embodiments. This method can be used to form the metal layers of FIGS. 2a, 3a, 7a, and 8a. In the example of FIG. 15, a metal layer can be deposited on a thin film substrate (1505). A photosensitive (or photo resist) layer can coat the metal layer (1510). A removable photo mask can be applied over the photosensitive layer, where the photo mask can include the desired pattern for the metal layer (1515). The mask can be exposed to light (1520). The photosensitive layer can be developed into the desired pattern based on the mask, thereby exposing particular portions of the metal layer for patterning (1525). The patterned photosensitive layer can function as an etching mask for the metal layer, where the exposed portions of the metal layer can be etched to form the desired pattern (1530). The photosensitive layer can be chemically stripped from the patterned metal layer (1535).

A method for patterning of a dielectric layer of a touch sensor panel according to various embodiments can be the same as the method of FIG. 15 except for the following difference. Rather than a metal layer being used, a dielectric layer can be used, resulting in a patterned dielectric layer for the touch sensor panel. Such a method can be used to form the dielectric layers of FIGS. 2b and 7b.

Although the invention has been fully described in connection with embodiments thereof with reference to the accompanying drawings, it is to be noted that various changes and modifications will become apparent to those skilled in the art. Such changes and modifications are to be understood as being included within the scope of the invention as defined by the appended claims.

What is claimed is:

1. A method comprising:
depositing a conductive layer onto a surface;
depositing a passivation layer onto the conductive layer;
applying a removable mask including a pattern to the passivation layer;
patterning the passivation layer to have the pattern;
providing the patterned passivation layer as a mask for the conductive layer; and
patterning the conductive layer to have the pattern.

2. The method of claim 1, wherein depositing the conductive layer comprises depositing the conductive layer onto the surface to form a first set of conductive traces and a second set of conductive traces crossing each other, and to form conductive bridges at the crossings of the first and second sets of conductive traces, the first and second sets of conductive traces and the conductive bridges for transmitting signals, the surface including a patterned dielectric layer disposed on a patterned metal layer.

3. The method of claim 1, wherein depositing the conductive layer comprises depositing the conductive layer onto the surface to form multiple conductive traces adjacent to each other, the multiple conductive traces for bonding to other circuitry, the surface including a patterned metal layer.

4. The method of claim 1, wherein depositing the passivation layer comprises depositing a photosensitive passivation layer configured to react to light upon exposure to the light, the reaction eliminating portions of the passivation layer.

5. The method of claim 1, wherein applying the removable mask comprises applying a photo mask configured to include multiple portions, each portion transmitting different intensities of light.

6. The method of claim 1, wherein patterning the passivation layer comprises forming a pattern of different thicknesses of the passivation layer, the thicknesses ranging from a thickness portion of the layer being removed to a thickness portion of the layer being unchanged.

7. The method of claim 1, wherein providing the patterned passivation layer as a mask comprises providing portions of the pattern in which the passivation layer is eliminated so that the underlying conductive layer is exposed.

8. The method of claim 1, wherein patterning the conductive layer comprises forming a pattern corresponding to the passivation layer pattern, eliminated portions of the conductive layer corresponding to previously eliminated portions of the passivation layer.

9. The method of claim 1, comprising:
forming a conductive bridge configured to transmit signals along the conductive layer; and
forming a bonding area configured to connect to other circuitry,
wherein applying the removable mask comprises applying the mask having a first pattern and a second pattern, the first pattern being applied to the passivation layer deposited on the portion of the conductive layer forming the conductive bridge and the second pattern being applied to the passivation layer deposited on the portion of the conductive layer forming the bonding area, and
wherein patterning the passivation layer comprises forming different thicknesses for the portion of the passivation layer deposited on the portion of the conductive layer forming the conductive bridge and the portion of the passivation layer deposited on the portion of the conductive layer forming the bonding area.

10. The method of claim 9, comprising:
removing the passivation layer from the portion of the conductive layer forming the bonding area; and
reducing the thickness of the passivation layer on the portion of the conductive layer forming the conductive bridge.

11. A method comprising:
depositing a conductive layer onto a surface;
depositing a passivation layer onto the conductive layer;
depositing a protective layer onto the passivation layer;
applying a removable mask including a pattern to the protective layer;
patterning the protective layer to have the pattern;
providing the patterned protective layer as a mask for the passivation layer and the conductive layer; and
patterning the passivation layer and the conductive layer to have the pattern.

12. The method of claim 11, wherein depositing the passivation layer comprises depositing a non-photosensitive passivation layer configured to be insensitive to light.

13. The method of claim 11, wherein depositing the protective layer comprises depositing a photosensitive protective layer configured to react to light, the reaction eliminating portions of the protective layer.

14. The method of claim 11, comprising:
forming a conductive bridge configured to transmit signals along the conductive layer; and
forming a bonding area configured to connect to other circuitry,
wherein applying the removable mask comprises applying the mask having a first pattern to the protective layer deposited at the portion of the conductive layer forming the conductive bridge and having a second pattern to the protective layer deposited at the portion of the conductive layer forming the bonding area, and
wherein patterning the protective layer comprises forming different thicknesses for the portion of the protective layer deposited at the portion of the conductive layer forming the conductive bridge and the portion of the protective layer deposited at the portion of the conductive layer forming the bonding area.

15. The method of claim 14, comprising:
removing the protective layer from the portion of the conductive layer forming the bonding area;
removing the passivation layer from the portion of the conductive layer forming the bonding area; and
maintaining the protective layer at the portion of the conductive layer forming the conductive bridge during the removing of the passivation layer.

16. The method of claim 11, comprising removing the protective layer.

17. A touch sensor panel comprising:
a touch area comprising
a first set of conductive traces and a second set of conductive traces forming touch sensors to sense a touch at the panel, and
multiple conductive bridges at crossings of the first and second sets of conductive traces to separate the first and second conductive traces from each other and to conduct signals associated with the sensed touch along the first and second conductive traces at the crossings, each conductive bridge comprising a passivation layer disposed on the first and second conductive traces, the passivation layer and the first and second conductive traces formed together into a same pattern at the bridge; and
a bonding area comprising
a third set of conductive traces forming connectors to connect the panel to associated circuitry, each of the third conductive traces having the passivation layer removed therefrom.

18. The panel of claim 17 incorporated into at least one of a mobile telephone, a digital media player, or a personal computer.

19. A method comprising:
providing a conductive layer configured to transmit signals of an electronic device;
providing a passivation layer configured to protect the conductive layer; and
patterning the conductive layer and the passivation layer together into a same pattern.

20. The method of claim 19, comprising:
applying a first mask including the pattern to the passivation layer to form the passivation layer into the pattern; and
applying the patterned passivation layer as a second mask for the conductive layer to form the conductive layer into the pattern.

21. The method of claim 19, comprising applying a mask having multiple portions with different transparencies, the transparencies corresponding to the pattern.

22. The method of claim 19, comprising applying a mask having multiple portions with different slit densities, the slit densities corresponding to the pattern.

23. The method of claim 19, comprising applying a mask including the pattern to the passivation layer, the mask configured to adjust the thickness of the passivation layer according to the pattern.

24. A device comprising:
at least one conductive layer configured to transmit signals of the device; and
at least one passivation layer configured to protect the conductive layer from damage,
the passivation layer and the conductive layer formed into a same pattern on the device from a removable mask including the pattern to form the passivation layer into the pattern and from the patterned passivation layer functioning as a mask to form the conductive layer into the pattern.

25. The device of claim 24, comprising:
at least another conductive layer configured to connect the device to related circuitry, the at least another conductive layer formed into another pattern on the device with the passivation layer removed therefrom.
